(19) United States
(12) Patent Application Publication
(10) Pub. No.: US 2026/0106425 A1
(43) Pub. Date: Apr. 16, 2026

(54) GAS LASER DEVICE AND ELECTRONIC DEVICE MANUFACTURING METHOD

(71) Applicant: Gigaphoton Inc., Oyama-shi (JP)

(72) Inventors: Yuki ODA, Oyama-shi (JP); Takuya SHIMAMURA, Oyama-shi (JP)

(73) Assignee: Gigaphoton Inc., Oyama-shi (JP)

(21) Appl. No.: 19/409,256

(22) Filed: Dec. 4, 2025

Related U.S. Application Data
(63) Continuation of application No. PCT/JP2023/026890, filed on Jul. 21, 2023.

(51) Int. Cl. H01S 3/034; G03F 7/00; G03F 7/20; H01S 3/08

(52) U.S. Cl. CPC H01S 3/034; G03F 7/2004; G03F 7/70025; G03F 7/70041; H01S 3/08059

(57) ABSTRACT

A gas laser device includes a chamber device outputting light generated from laser gas, a resonator causing the light output from the chamber device to resonate, and a beam expander. The resonator includes an output coupling mirror arranged on one side of the sides sandwiching the chamber device, and causes a part of the light to be transmitted therethrough, and another part thereof to return into the chamber device. The beam expander is arranged between the chamber device and the output coupling mirror and includes a holding portion, a convex mirror including a reflection surface reflecting the light output from the chamber device to expand a beam width of the laser light, and a concave mirror including a reflection surface reflecting the light reflected by the convex mirror toward the output coupling mirror so as to collimate the light so that the expanded beam width of the light becomes constant.

### CROSS-REFERENCE TO RELATED APPLICATIONS

The present application is a continuation application of International Application No. PCT/JP2023/026890, filed on Jul. 21, 2023, the entire contents of which are hereby incorporated by reference.

### BACKGROUND

### 1. Technical Field

The present disclosure relates to a gas laser device, and an electronic device manufacturing method.

### 2. Related Art

Recently, in a semiconductor exposure apparatus, improvement in resolution has been desired for miniaturization and high integration of semiconductor integrated circuits. For this purpose, an exposure light source that outputs light having a shorter wavelength has been developed. For example, as a gas laser device for exposure, a KrF excimer laser device for outputting laser light having a wavelength of about 248.0 nm and an ArF excimer laser device for outputting laser light having a wavelength of about 193.4 nm are used.

The KrF excimer laser device and the ArF excimer laser device each have a large spectral line width of about 350 pm to 400 pm in natural oscillation light. Therefore, when a projection lens is formed of a material that transmits ultraviolet rays such as KrF laser light and ArF laser light, there is a case in which chromatic aberration occurs. As a result, the resolution may decrease. Then, a spectral line width of laser light output from the gas laser device needs to be line-narrowed to the extent that the chromatic aberration can be ignored. For this purpose, there is a case in which a line narrowing module (LNM) including a line narrowing element (etalon, grating, and the like) is provided in a laser resonator of the gas laser device to line-narrow a spectral line width. In the following, a gas laser device with a narrowed spectral line width is referred to as a line narrowing gas laser device.

### LIST OF DOCUMENTS

### Patent Documents

Patent Document 1: Japanese Patent Application Publication No. 2016-018076
Patent Document 2: US Patent Application Publication No. 2021/0336407

### SUMMARY

A gas laser device according to an aspect of the present disclosure includes a chamber device including a pair of discharge electrodes facing each other and arranged at an internal space thereof in which a laser gas is filled, and configured to output light generated from the laser gas by a voltage being applied between the pair of discharge electrodes; a resonator configured to cause the light output from the chamber device to resonate between both sides sandwiching the chamber device; and a beam expander. Here, the resonator includes an output coupling mirror arranged on one side of the sides sandwiching the chamber device, and is configured to cause a part of the light output from the chamber device to be transmitted therethrough, and another part of the light output from the chamber device to be reflected to return into the chamber device. The beam expander is arranged between the chamber device and the output coupling mirror, and includes a holding portion; a convex mirror including a reflection surface reflecting the light output from the chamber device to expand a beam width of the light, and a plurality of side surfaces with only one side surface among the plurality of side surfaces fixed to the holding portion by an adhesive; and a concave mirror including a reflection surface reflecting the light reflected by the convex mirror toward the output coupling mirror so as to collimate the light so that the expanded beam width of the light becomes constant, and a plurality of side surfaces with only one side surface among the plurality of side surfaces fixed to the holding portion by an adhesive.

An electronic device manufacturing method according to an aspect of the present disclosure includes generating pulse laser light using a gas laser device, outputting the pulse laser light to an exposure apparatus, and exposing a photosensitive substrate to the pulse laser light in the exposure apparatus to manufacture an electronic device. Here, the gas laser device includes a chamber device including a pair of discharge electrodes facing each other and arranged at an internal space thereof in which a laser gas is filled, and configured to output light generated from the laser gas by a voltage being applied between the pair of discharge electrodes; a resonator configured to cause the light output from the chamber device to resonate between both sides sandwiching the chamber device; and a beam expander. The resonator includes an output coupling mirror arranged on one side of the sides sandwiching the chamber device, and is configured to cause a part of the light output from the chamber device to be transmitted therethrough, and another part of the light output from the chamber device to be reflected to return into the chamber device. The beam expander is arranged between the chamber device and the output coupling mirror, and includes a holding portion; a convex mirror including a reflection surface reflecting the light output from the chamber device to expand a beam width of the light, and a plurality of side surfaces with only one side surface among the plurality of side surfaces fixed to the holding portion by an adhesive; and a concave mirror including a reflection surface reflecting the light reflected by the convex mirror toward the output coupling mirror so as to collimate the light so that the expanded beam width of the light becomes constant, and a plurality of side surfaces with only one side surface among the plurality of side surfaces fixed to the holding portion by an adhesive.

### BRIEF DESCRIPTION OF THE DRAWINGS

Embodiments of the present disclosure will be described below merely as examples with reference to the accompanying drawings.

FIG. 1 is a schematic view showing a schematic configuration example of an entire electronic device manufacturing apparatus.

FIG. 2 is a schematic view showing a schematic configuration example of an entire gas laser device of a comparative example.

FIG. 3 is a schematic view showing a schematic configuration example of a beam expander of the comparative example.

FIG. 4 is a perspective view showing a convex mirror and a concave mirror of the comparative example.

FIG. 5 is a sectional view of the convex mirror.

FIG. 6 is a sectional view of the concave mirror.

FIG. 7 is a view showing a state in which the convex mirror is fixed to a convex mirror holder by an adhesive.

FIG. 8 is a view showing a state in which the concave mirror is fixed to a concave mirror holder by an adhesive.

FIG. 9 is a schematic view showing a schematic configuration example of the beam expander of a first embodiment in a similar manner to FIG. 3.

FIG. 10 is a sectional view of the beam expander taken along line X-X shown in FIG. 9.

FIG. 11 is a sectional view of the beam expander taken along line XI-XI shown in FIG. 9.

FIG. 12 is a schematic view showing a schematic configuration example of the beam expander of a second embodiment in a similar manner to FIG. 3.

FIG. 13 is a perspective view showing the convex mirror, a planar mirror, and the concave mirror of the second embodiment in a similar manner to FIG. 4.

FIG. 14 is a sectional view of the beam expander taken along line XIV-XIV shown in FIG. 12.

FIG. 15 is a schematic view showing a schematic configuration example of the beam expander of a third embodiment in a similar manner to FIG. 3.

FIG. 16 is a perspective view showing the convex mirror, a first planar mirror, a second planar mirror, and the concave mirror of the third embodiment in a similar manner to FIG. 4.

FIG. 17 is a sectional view of the beam expander taken along line XVII-XVII shown in FIG. 15.

### DESCRIPTION OF EMBODIMENTS

1. Description of electronic device manufacturing apparatus used in exposure process for electronic device
2. Description of gas laser device of comparative example
   2.1 Configuration
   2.2 Operation
   2.3 Problem
3. Description of gas laser device of first embodiment
   3.1 Configuration
   3.2 Operation
   3.3 Effect
4. Description of gas laser device of second embodiment
   4.1 Configuration
   4.2 Operation
   4.3 Effect
5. Description of gas laser device of third embodiment
   5.1 Configuration
   5.2 Operation
   5.3 Effect

Hereinafter, embodiments of the present disclosure will be described in detail with reference to the drawings. The embodiments described below show some examples of the present disclosure and do not limit the contents of the present disclosure. Also, all configurations and operation described in the embodiments are not necessarily essential as configurations and operation of the present disclosure. Here, the same components are denoted by the same reference numeral, and duplicate description thereof is omitted.

### 1. Description of Electronic Device Manufacturing Apparatus

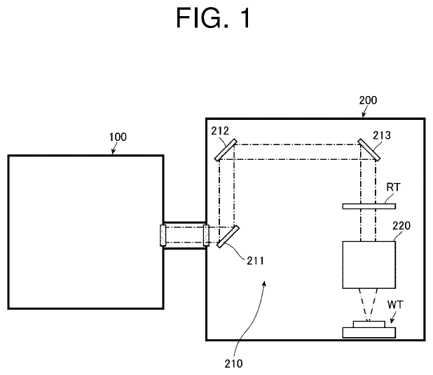

Used in Exposure Process for Electronic Device FIG. 1 is a schematic view showing a schematic configuration example of an entire electronic device manufacturing apparatus used in an exposure process for an electronic device. As shown in FIG. 1, the manufacturing apparatus used in the exposure process includes a gas laser device 100 and an exposure apparatus 200. The exposure apparatus 200 includes an illumination optical system 210 including a plurality of mirrors 211, 212, 213 and a projection optical system 220. The illumination optical system 210 illuminates a reticle pattern of a reticle stage RT with laser light entering from the gas laser device 100. The projection optical system 220 causes the laser light transmitted through the reticle to be imaged as being reduced and projected on a workpiece (not shown) arranged on a workpiece table WT. The workpiece is a photosensitive substrate such as a semiconductor wafer on which photoresist is applied. The exposure apparatus 200 synchronously translates the reticle stage RT and the workpiece table WT to expose the workpiece to the laser light reflecting the reticle pattern. Through the exposure process as described above, a device pattern is transferred onto the semiconductor wafer, thereby a semiconductor device, which is the electronic device, can be manufactured.

### 2. Description of Gas Laser Device of Comparative Example

### 2.1 Configuration

The gas laser device of a comparative example will be described. The comparative example of the present disclosure is an example recognized by the applicant as known only by the applicant, and is not a publicly known example admitted by the applicant.

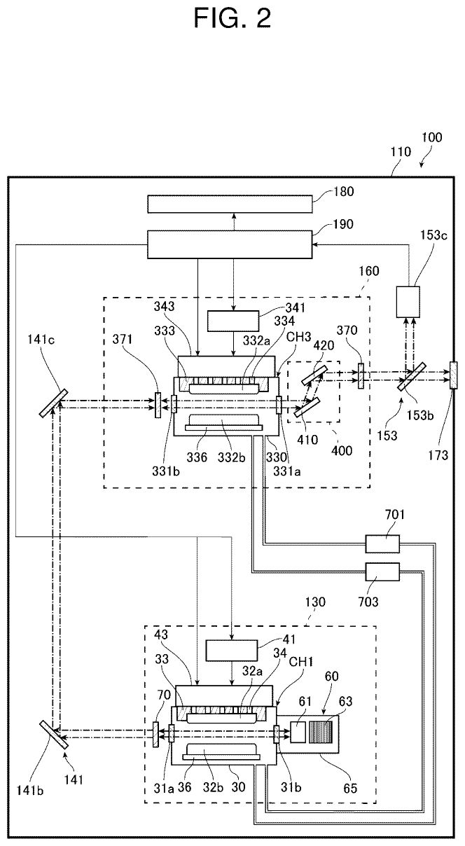

FIG. 2 is a schematic view showing a schematic configuration example of the entire gas laser device 100 of the present example. The gas laser device 100 is, for example, an ArF excimer laser device using a mixed gas including argon (Ar), fluorine (F₂), and neon (Ne). The gas laser device 100 outputs laser light having a center wavelength of about 193.4 nm. Here, the gas laser device 100 may be a gas laser device other than the ArF excimer laser device, and may be, for example, a KrF excimer laser device using a mixed gas including krypton (Kr), F₂, and Ne. In this case, the gas laser device 100 outputs laser light having a center wavelength of about 248.0 nm. The mixed gas containing Ar, F₂, and Ne which is a laser medium and the mixed gas containing Kr, F₂, and Ne which is a laser medium may be each referred to as a laser gas. In the mixed gas used in each of the ArF excimer laser device and the KrF excimer laser device, helium (He) may be used instead of Ne.

The gas laser device 100 of the present example includes a housing 110, and a laser oscillator 130 that is a master oscillator, an optical transmission unit 141, an amplifier 160 that is a power oscillator, a detection unit 153, a display unit 180, a processor 190, a laser gas exhaust device 701, and a laser gas supply device 703 arranged at the internal space of the housing 110 as a main configuration.

The laser oscillator 130 includes a chamber device CH1, a charger 41, a pulse power module 43, a line narrowing module 60, and an output coupling mirror 70 as a main configuration.

In FIG. 2, the internal configuration of the chamber device CH1 is shown as viewing from a direction substantially perpendicular to the travel direction of the laser light. The chamber device CH1 includes a housing 30, a pair of windows 31a, 31b, a pair of electrodes 32a, 32b, an insulating portion 33, a feedthrough 34, and an electrode holder portion 36 as a main configuration.

The housing 30 is supplied with the laser gas from the laser gas supply device 703 to the internal space of the housing 30 via a pipe, and the internal space is filled with the laser gas. The internal space is a space in which light is generated by excitation of the laser medium in the laser gas. This light travels to the windows 31a, 31b.

The window 31a is arranged at a wall surface of the housing 30 on the front side in the travel direction of the laser light from the gas laser device 100 to the exposure apparatus 200, and the window 31b is arranged at a wall surface of the housing 30 on the rear side in the travel direction. The windows 31a, 31b are calcium fluoride substrates, and surfaces of the windows 31a, 31b on the inner side and the outer side of the housing 30 are flat surfaces. Here, the windows 31a, 31b are not limited to the calcium fluoride substrate as long as being capable of transmitting the laser light. The windows 31a, 31b are inclined at the Brewster angle with respect to the travel direction of the laser light so that P-polarized light of the laser light is suppressed from being reflected.

The electrodes 32a, 32b are arranged to face each other at the internal space of the housing 30, and the longitudinal direction of the electrodes 32a, 32b is along the travel direction of the light generated by the high voltage applied between the electrode 32a and the electrode 32b. The space between the electrode 32a and the electrode 32b in the housing 30 is sandwiched by the window 31a and the window 31b. The electrodes 32a, 32b are discharge electrodes for exciting the laser medium by glow discharge. In the present example, the electrode 32a is the cathode and the electrode 32b is the anode.

The electrode 32a is supported by the insulating portion 33. The insulating portion 33 blocks an opening formed in the housing 30. The insulating portion 33 includes an insulator. Further, the feedthrough 34 made of a conductive member is arranged in the insulating portion 33. The feedthrough 34 applies a voltage, to the electrode 32a, supplied from the pulse power module 43. The electrode 32b is supported by the electrode holder portion 36 and is electrically connected to the electrode holder portion 36.

The charger 41 is a DC power source device that charges a capacitor (not shown) provided in the pulse power module 43 with a predetermined voltage. The charger 41 is arranged outside the housing 30 and is connected to the pulse power module 43. The pulse power module 43 includes a switch (not shown) controlled by the processor 190. The pulse power module 43 is a voltage application circuit that, when the switch is turned ON from OFF by the control, boosts the voltage applied from the charger 41 to generate a pulse high voltage, and applies the high voltage to the electrodes 32a, 32b. When the high voltage is applied, discharge occurs between the electrode 32a and the electrode 32b. The energy of the discharge excites the laser medium in the housing 30. When the excited laser gas shifts to a ground level, light is emitted, and the emitted light is transmitted through the windows 31a, 31b and is output to the outside of the housing 30.

The line narrowing module 60 includes a housing 65, and a prism 61, a grating 63, and a rotation stage (not shown) arranged at the internal space of the housing 65. An opening is formed in the housing 65, and the housing 65 is connected to the rear side of the housing 30 via the opening.

The prism 61 expands the beam width of the light output from the window 31b and causes the light to be incident on the grating 63. The prism 61 also reduces the beam width of the light reflected from the grating 63 and returns the light to the internal space of the housing 30 via the window 31b. The prism 61 is supported by the rotation stage and is rotated by the rotation stage. The incident angle of the light with respect to the grating 63 is changed by the rotation of the prism 61. Therefore, by rotating the prism 61, the wavelength of the light returning from the grating 63 to the housing 30 via the prism 61 can be selected. Although FIG. 2 shows an example in which one prism 61 is arranged, two or more prisms may be arranged.

The surface of the grating 63 is configured of a material having a high reflectance, and a large number of grooves are formed on the surface at predetermined intervals. The grating 63 is a dispersive optical element. The sectional shape of each groove is, for example, a right-angled triangle. The light incident on the grating 63 from the prism 61 is reflected by these grooves and diffracted in a direction corresponding to the wavelength of the light. The grating 63 is arranged in the Littrow arrangement, which causes the incident angle of the light incident on the grating 63 from the prism 61 to coincide with the diffraction angle of the diffracted light having a desired wavelength. Thus, light having a desired wavelength returns to the housing 30 via the prism 61.

The output coupling mirror 70 faces the window 31a, transmits a part of the laser light output from the window 31a, and reflects another part thereof to return to the internal space of the housing 30 via the window 31a. The output coupling mirror 70 is fixed to a holder (not shown) and is arranged at the internal space of the housing 110.

The grating 63 and the output coupling mirror 70 arranged with the housing 30 interposed therebetween configure a Fabry-Perot resonator, and the housing 30 is arranged on the optical path of the resonator. Accordingly, the resonator causes the light to resonate between both sides sandwiching the chamber device CH1.

The optical transmission unit 141 includes high reflection mirrors 141b, 141c as a main configuration. The high reflection mirrors 141b, 141c are respectively fixed to holders (not shown) with inclination angles thereof adjusted, and are arranged at the internal space of the housing 110. The high reflection mirrors 141b, 141c highly reflect the laser light. The high reflection mirrors 141b, 141c are arranged on the optical path of the laser light from the output coupling mirror 70. The laser light is reflected by the high reflection mirrors 141b, 141c and travels to a rear mirror 371 of the amplifier 160. At least a part of the laser light is transmitted through the rear mirror 371.

The amplifier 160 amplifies the energy of the laser light output from the laser oscillator 130. The basic configuration of the amplifier 160 is substantially the same as that of the laser oscillator 130. In order to distinguish the components of the amplifier 160 from the components of the laser oscillator 130, description is performed as a chamber device CH3, a housing 330, a pair of windows 331a, 331b, a pair of electrodes 332a, 332b, an insulating portion 333, a feedthrough 334, an electrode holder portion 336, a charger 341, a pulse power module 343, and an output coupling mirror 370. The electrodes 332a, 332b cause discharge for amplifying the laser light from the laser oscillator 130. Similarly to the pulse power module 43, the pulse power module 343 is a voltage application circuit.

The amplifier 160 is mainly different from the laser oscillator 130 in that the line narrowing module 60 is not included and the rear mirror 371 and a beam expander 400 are included.

The rear mirror 371 is provided between the high reflection mirror 141c and the window 331b and faces to both thereof. The rear mirror 371 transmits a part of the laser light from the laser oscillator 130 toward the space between the electrodes 332a, 332b, and reflects a part of the laser light amplified by the electrodes 332a, 332b toward the space between the electrodes 332a, 332b.

The output coupling mirror 370 is arranged on a side opposite to the rear mirror 371 with respect to the chamber device CH3, and the beam expander 400 is arranged between the chamber device CH3 and the output coupling mirror 370.

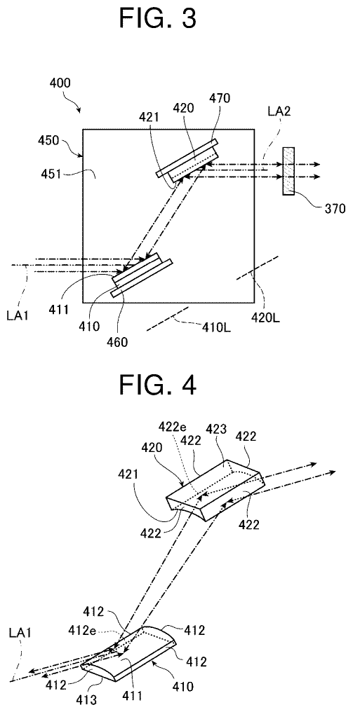

FIG. 3 is a schematic view showing a schematic configuration example of the beam expander 400 of the present example, and is a schematic view of the beam expander 400 viewed along a direction perpendicular to an optical axis LA1 of the laser light output from the window 331a and perpendicular to a direction in which the electrodes 332a, 332b face each other. As shown in FIG. 3, in the present example, the beam expander 400 includes a convex mirror 410, a concave mirror 420, and a holding portion 450.

FIG. 4 is a perspective view showing the convex mirror 410 and the concave mirror 420 of the present example. The convex mirror 410 is a plate-like member, and includes a reflection surface 411 that reflects light, a plurality of side surfaces 412, and a back surface 413 that is located on the back side of the reflection surface 411 and faces the reflection surface 411. The concave mirror 420 is a plate-like member, and includes a reflection surface 421 that reflects light, a plurality of side surfaces 422, and a back surface 423 that is located on the back side of the reflection surface 421 and faces the reflection surface 421. The reflection surface 411 of the convex mirror 410 reflects the laser light from the chamber device CH3 toward the concave mirror 420 so as to expand the beam width of the laser light. The reflection surface 421 of the concave mirror 420 reflects the laser light, reflected by the convex mirror 410, toward the output coupling mirror 370 to collimate the laser light so that the expanded beam width of the laser light becomes constant. The concave mirror 420 reflects the laser light from the output coupling mirror 370 toward the convex mirror 410 such that the beam width of the laser light is reduced. The convex mirror 410 reflects the laser light, reflected by the concave mirror 420, toward the chamber device CH3 so that the reduced beam width of the laser light becomes constant, and the laser light returns to the internal space of the housing 330 via the window 331a.

In the present example, the convex mirror 410 is a convex cylindrical mirror, and the shape of the convex mirror 410 when the reflection surface 411 is viewed from the front is a rectangle elongated in a direction parallel to a focal line 410L of the convex mirror 410. Further, the concave mirror 420 is a concave cylindrical mirror, and the shape of the concave mirror 420 when the reflection surface 421 is viewed from the front is a rectangle elongated in a direction parallel to a focal line 420L of the concave mirror 420. Thus, the convex mirror 410 includes the four planar side surfaces 412, and the concave mirror 420 includes the four planar side surfaces 422. Here, the focal line 410L is a line connecting focal points of the convex mirror 410, and the focal line 420L is a line connecting focal points of the concave mirror 420. Further, the shapes of the convex mirror 410 and the concave mirror 420 and the numbers of the side surfaces 412, 422 are not limited. For example, the shape of the convex mirror 410 may be a rectangle elongated in a direction perpendicular to the focal line 410L, and the shape of the concave mirror 420 may be a rectangle elongated in a direction perpendicular to the focal line 420L.

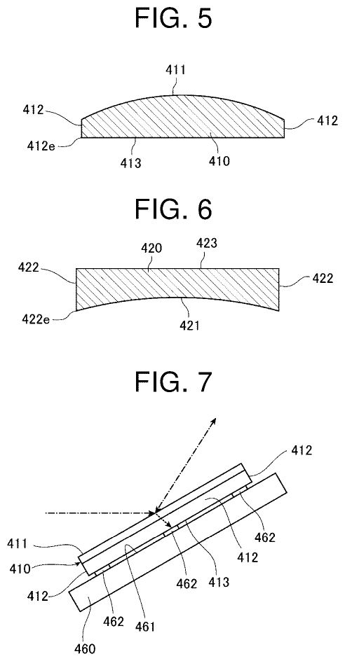

FIG. 5 is a sectional view of the convex mirror 410, and the cross section is parallel to a normal line of the reflection surface 411 of the convex mirror 410 and perpendicular to the plane of incidence of the laser light output from the window 331a with respect to the reflection surface 411. Although the shape of the reflection surface 411 in the cross section is an arc in FIG. 5, the shape is not limited, and may be, for example, a parabola.

FIG. 6 is a sectional view of the concave mirror 420, and the cross section is parallel to a normal line of the reflection surface 421 of the concave mirror 420 and perpendicular to the plane of incidence of the laser light reflected by the convex mirror 410 toward the concave mirror 420 with respect to the reflection surface 421. Although the shape of the reflection surface 421 in the cross section is an arc in FIG. 6, the shape is not limited, and may be, for example, a parabola.

Returning to FIG. 3, the focal line 410L of the convex mirror 410 is included in the plane including the optical axis LA1 of the laser light and extending in the direction in which the electrodes 332a, 332b face each other, and is inclined so as to approach the electrode 332a as the distance from the chamber device CH3 increases. Further, the focal line 420L of the concave mirror 420 is included in a plane including the optical axis LA1 of the laser light and the focal line 410L, and is inclined so as to approach the electrode 332a as the distance from the chamber device CH3 increases. The focal line 410L and the focal line 420L are located on the same straight line. That is, the positions of the convex mirror 410 and the concave mirror 420 are adjusted as described above. Here, the focal line 410L and the focal line 420L may not be located on the same straight line.

The holding portion 450 holds the convex mirror 410 and the concave mirror 420. In the present example, the holding portion 450 includes a base member 451, a convex mirror holder 460, and a concave mirror holder 470.

The convex mirror holder 460 of the present example is a plate-like member extending along the back surface 413 of the convex mirror 410, and the back surface 413 of the convex mirror 410 is fixed to a main surface 461 on the convex mirror 410 side by an adhesive. FIG. 7 is a view showing a state in which the convex mirror 410 is fixed to the convex mirror holder 460 by an adhesive. As shown in FIG. 7, the adhesive 462 is separated into a plurality of adhesive portions. Since the adhesive 462 is arranged between the main surface 461 of the convex mirror holder 460 and the back surface 413 of the convex mirror 410, the main surface 461 and the back surface 413 are separated from each other, and a space is formed in a region where the adhesive 462 is not arranged between the main surface 461 and the back surface 413. The adhesive 462 may be, for example, an ultraviolet curable adhesive, and the ultraviolet curable adhesive may be, for example, an urethane acrylate adhesive. Here, the adhesive 462 may not be separated into a plurality of adhesive portions.

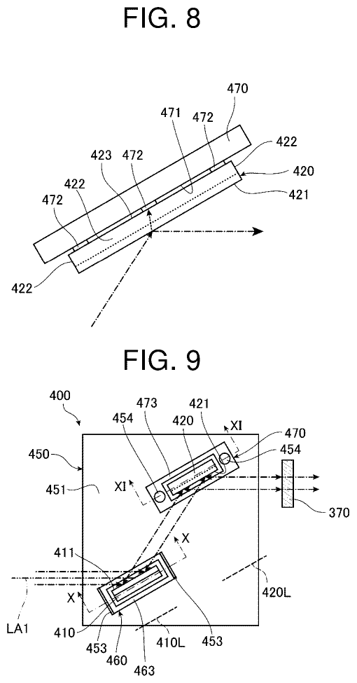

The concave mirror holder 470 of the present example is a plate-like member extending along the back surface 423 of the concave mirror 420, and the back surface 423 of the concave mirror 420 is fixed to the main surface 471 on the concave mirror 420 side by an adhesive. FIG. 8 is a view showing a state in which the concave mirror 420 is fixed to the concave mirror holder 470 by an adhesive. As shown in FIG. 8, similarly to the adhesive 462, the adhesive 472 that fixes the back surface 423 to the main surface 471 is separated into a plurality of adhesive portions. Thus, since the adhesive 472 is arranged between the main surface 471 and the back surface 423, the main surface 471 and the back surface 423 are separated from each other, and a space is formed in a region where the adhesive 472 is not arranged between the main surface 471 and the back surface 423. The adhesive 472 may be, for example, an adhesive similar to the adhesive 462. Here, the adhesive 472 may not be separated into a plurality of adhesive portions.

The base member 451 of the present example is a plate-shaped member extending in a direction parallel to the optical axis LA1 of the laser light output from the window 331a of the chamber device CH3. In the present example, the base member 451 extends in the direction in which the electrodes 332a, 332b face each other, and the convex mirror holder 460 and the concave mirror holder 470 are fixed to one main surface 452 of the base member 451. Thus, the convex mirror 410 is fixed to the base member 451 via the convex mirror holder 460, and the concave mirror 420 is fixed to the base member 451 via the concave mirror holder 470. Therefore, the convex mirror 410 is fixed to the holding portion 450 by the adhesive 462, the concave mirror 420 is fixed to the holding portion 450 by the adhesive 472, and the convex mirror 410 and the concave mirror 420 are held by the holding portion 450.

Returning to FIG. 2, the surface of the output coupling mirror 370 on the beam expander 400 side is coated with a partial reflection film having a predetermined reflectance. The output coupling mirror 370 reflects a part of the laser light from the chamber device CH3 with the beam width thereof expanded by the beam expander 400 toward the beam expander 400, and transmits another part of the laser light.

The output coupling mirror 370 may have a circular shape. The surface of the output coupling mirror 370 on the beam expander 400 side and the surface opposite to the surface may be flat surfaces. Configurations of the rear mirror 371 and the output coupling mirror 370 are similar to that of the output coupling mirror 70.

The rear mirror 371 and the output coupling mirror 370 arranged with the housing 330 interposed therebetween configure a resonator in which the laser light amplified by the electrodes 332a, 332b resonates. The housing 330 and the beam expander 400 are arranged on the optical path of the resonator. The laser light output from the window 331a of the housing 330 is incident on the output coupling mirror 370 via the beam expander 400, and is reflected by the output coupling mirror 370. The laser light reflected by the output coupling mirror 370 returns to the internal space of the housing 330 via the beam expander 400 and the window 331b, and is output from the window 331a. The laser light output from the window 331a is reflected by the rear mirror 371 and returns to the internal space of the housing 330 via the window 331b. Thus, the laser light output from the housing 330 reciprocates between the rear mirror 371 and the output coupling mirror 370. The reciprocating laser light is amplified every time the laser light passes through a laser gain space between the electrode 332a and the electrode 332b. That is, the resonator resonates light between both sides sandwiching the chamber device CH3, and the output coupling mirror 370 is arranged on one side of sandwiching the chamber device CH3. A part of the amplified laser light is transmitted through the output coupling mirror 370. The laser light transmitted through the output coupling mirror 370 travels to the detection unit 153.

The detection unit 153 includes a beam splitter 153b and an optical sensor 153c as a main configuration.

The beam splitter 153b is arranged on the optical path of the laser light transmitted through the output coupling mirror 370. The beam splitter 153b transmits the laser light transmitted through the output coupling mirror 370 toward an output window 173 with a high transmittance, and reflects a part of the laser light toward a light receiving surface of the optical sensor 153c.

The optical sensor 153c measures the pulse energy of the laser light incident on the light receiving surface of the optical sensor 153c. The optical sensor 153c is electrically connected to the processor 190, and outputs a signal indicating the measured pulse energy to the processor 190. The processor 190 controls the voltage to be applied to the electrodes 332a, 332b of the amplifier 160 based on the signal.

The output window 173 is provided on the opposite side of the output coupling mirror 370 with respect to the beam splitter 153b of the detection unit 153. The output window 173 is provided in a wall of the housing 110. The light transmitted through the beam splitter 153b is output from the output window 173 to the exposure apparatus 200 outside the housing 110. The laser light is, for example, pulse laser light having a center wavelength of 193.4 nm.

The display unit 180 is a monitor that displays a state of control by the processor 190 based on a signal from the processor 190. The display unit 180 may be arranged outside the housing 110.

The processor 190 of the present disclosure is a processing device including a storage device in which a control program is stored and a central processing unit (CPU) that executes the control program. The processor 190 is specifically configured or programmed to perform various processes included in the present disclosure. The processor 190 controls the entire gas laser device 100. The processor 190 is electrically connected to an exposure processor (not shown) of the exposure apparatus 200, and transmits and receives various signals to and from the exposure processor.

The laser gas exhaust device 701 and the laser gas supply device 703 are electrically connected to the processor 190. The laser gas exhaust device 701 includes an exhaust pump (not shown), and exhausts the laser gas from the internal spaces of the housings 30, 330 via a pipe by suction of the exhaust pump according to a control signal from the processor 190. The laser gas supply device 703 supplies the laser gas from a laser gas supply source (not shown) arranged outside the housing 110 to the internal spaces of the housings 30, 330 via a pipe according to a control signal from the processor 190.

### 2.2 Operation

Next, operation of the gas laser device 100 of the comparative example will be described.

In a state before the gas laser device 100 outputs the laser light, the laser gas is supplied from the laser gas supply device 703 to the internal spaces of the housings 30, 330.

When the gas laser device 100 outputs the laser light, the processor 190 receives a signal indicating a target energy Et and a light emission trigger signal from the exposure processor (not shown) of the exposure apparatus 200. The target energy Et is a target value of the energy of the laser light to be used in the exposure process. The processor 190 sets a predetermined charge voltage to the charger 41 so that the energy E becomes the target energy Et, and turns ON the switch of the pulse power module 43 in synchronization with the light emission trigger signal. Thus, the pulse power module 43 generates a pulse high voltage from the electric energy held in the charger 41, and applies the high voltage between the electrode 32a and the electrode 32b. When the high voltage is applied, discharge occurs between the electrode 32a and the electrode 32b, the laser medium contained in the laser gas between the electrode 32a and the electrode 32b is brought into an excited state, and light is emitted when the laser medium returns to the ground state. The emitted light resonates between the grating 63 and the output coupling mirror 70, and is amplified every time passing through the discharge space at the internal space of the housing 30, so that laser oscillation occurs. The laser light includes first linear polarization, and linear polarization whose polarization direction is different from the first linear polarization is reduced from the laser light transmitted through the windows 31a, 31b. A part of the laser light is transmitted through the output coupling mirror 70, is reflected by the high reflection mirrors 141b, 141c, is transmitted through the rear mirror 371 and the window 331b, and travels into the housing 330.

The processor 190 turns ON the switch of the pulse power module 343 so that discharge occurs when the laser light from the laser oscillator 130 travels to the discharge space in the housing 330. That is, the processor 190 controls the pulse power module 343 so that a high voltage is applied to the electrodes 332a, 332b after a predetermined delay time elapses from the timing at which the switch of the pulse power module 43 is turned ON.

Thus, the laser light having entered the amplifier 160 is amplified in the amplifier 160. Further, the laser light traveling to the internal space of the housing 330 is output from the window 331a as described above and travels to the beam expander 400. The laser light having traveled to the beam expander 400 is reflected by the convex mirror 410 toward the concave mirror 420. The sectional shape of the reflection surface 411 of the convex mirror 410 is an arc, and the focal line 410L of the convex mirror 410 is included in a plane including the optical axis LA1 of the laser light and extending in the direction in which the electrodes 332a, 332b face each other. Therefore, the laser light output from the window 331a is reflected by the convex mirror 410 toward the concave mirror 420 so that the beam width of the laser light is expanded in the direction perpendicular to the direction in which the electrodes 332a,332b face each other.

The laser light whose beam width is expanded is reflected by the concave mirror 420 toward the output coupling mirror 370. The sectional shape of the reflection surface 421 of the concave mirror 420 is an arc, and the focal line 410L of the convex mirror 410 and the focal line 420L of the concave mirror 420 are included in the same plane including the optical axis LA1 of the laser light, and the focal line 410L and the focal line 420L are located on the same straight line. Therefore, the laser light whose beam width is expanded is reflected by the concave mirror 420 to be collimated so that the expanded beam width becomes constant. Then, the collimated laser light is incident on the output coupling mirror 370.

A part of the laser light incident on the output coupling mirror 370 is reflected by the output coupling mirror 370, and reflected by the concave mirror 420 toward the convex mirror 410. The beam width of the laser light is reduced in the direction perpendicular to the direction in which the electrodes 332a, 332b face each other. The laser light whose beam width is reduced is reflected by the convex mirror 410 toward the window 331a. This laser light is collimated so that the reduced beam width becomes constant, travels to the internal space of the housing 330 via the window 331a, and is output from the window 331b. The light output from the window 331b is reflected by the rear mirror 371 and travels through the internal space of the housing 330 via the window 331b. Thus, the laser light having a predetermined wavelength reciprocates between the rear mirror 371 and the output coupling mirror 370. The laser light is amplified every time passing through the discharge space at the internal space of the housing 330, and a part of the laser light becomes amplified laser light.

The amplified laser light from the amplifier 160 is transmitted through the output coupling mirror 370 and travels to the beam splitter 153b.

A part of the amplified laser light having traveled to the beam splitter 153b is transmitted through the beam splitter 153b and the output window 173 and travels to the exposure apparatus 200, while another part is reflected by the beam splitter 153b and travels to the optical sensor 153c.

The optical sensor 153c measures the energy E of the received amplified laser light. The optical sensor 153c outputs a signal indicating the measured energy E to the processor 190. The processor 190 performs feedback control on the charge voltages of the chargers 41, 341 so that a difference ΔE between the energy E and the target energy Et is within an allowable range. When the difference ΔE is within the allowable range, the laser light is transmitted through the beam splitter 153b and the output window 173 and enters the exposure apparatus 200.

### 2.3 Problem

In the comparative example, the beam expander 400 expands the beam width of the laser light output from the chamber device CH3 by the convex mirror 410 and the concave mirror 420, and outputs the light toward the output coupling mirror 370. Therefore, the energy density of the laser light incident on the output coupling mirror 370 can be reduced, and deterioration of the output coupling mirror 370 over time can be suppressed. In general, a reflection surface of a reflection member that reflects light reflects most of the incident light, but a part of the incident light is transmitted through the reflection member without being reflected by the reflection surface. Therefore, a part of the laser light incident on the reflection surface 411 of the convex mirror 410 travels inside the convex mirror 410 and is output from the back surface 413 facing the reflection surface 411. Further, a part of the laser light incident on the reflection surface 421 of the concave mirror 420 travels inside the concave mirror 420 and is output from the back surface 423 facing the reflection surface 421. In the comparative example, the back surface 413 of the convex mirror 410 is fixed to the convex mirror holder 460 by the adhesive 462, and the back surface 423 of the concave mirror 420 is fixed to the concave mirror holder 470 by the adhesive 472. Therefore, there is a fear that the adhesives 462, 472 are to be deteriorated by being irradiated with the laser light, and that durability of the gas laser device is deteriorated.

Therefore, in the following embodiments, a gas laser device capable of suppressing a decrease in durability is exemplified.

### 3. Description of Gas Laser Device of First Embodiment

Next, the gas laser device 100 of a first embodiment will be described. Any component same as that described above is denoted by an identical reference sign, and duplicate description thereof is omitted unless specific description is needed. Further, in some drawings, a part of a member may be omitted or simplified for easy viewing.

### 3.1 Configuration

FIG. 9 is a schematic view showing a schematic configuration example of the beam expander 400 of a first embodiment in a similar manner to FIG. 3. As shown in FIG. 9, in the beam expander 400 of the present embodiment, the configurations of the convex mirror holder 460 and the concave mirror holder 470 are mainly different from the configurations of the convex mirror holder 460 and the concave mirror holder 470 of the comparative example.

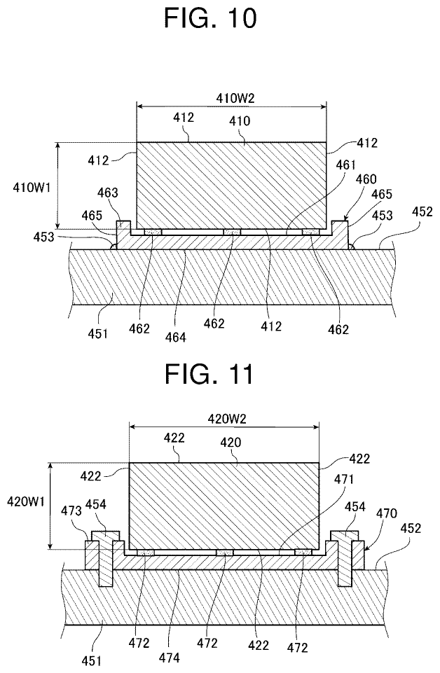

FIG. 10 is a sectional view of the beam expander 400 at line X-X shown in FIG. 9 and is a sectional view of the beam expander 400 in a section across the convex mirror 410 and parallel to the focal line 410L. As shown in FIG. 10, the convex mirror holder 460 of the present embodiment is a plate-like member extending along a specific side surface 412 which is one of the two side surfaces 412 extending along the longitudinal direction of the convex mirror 410. Only one specific side surface 412 of the convex mirror 410 is fixed to the main surface 461 of the convex mirror holder 460 on the convex mirror 410 side by the adhesive 462. The adhesive 462 is separated into a plurality of adhesive portions. Since the adhesive 462 is arranged between the main surface 461 of the convex mirror holder 460 and the specific side surface 412 of the convex mirror 410, the main surface 461 and the specific side surface 412 are separated from each other, and a space is formed in a region where the adhesive 462 is not arranged between the main surface 461 and the specific side surface 412. Here, the adhesive 462 may not be separated into a plurality of adhesive portions.

The convex mirror holder 460 includes a convex mirror protrusion 463 protruding from the main surface 461 and arranged around the convex mirror 410. The convex mirror protrusion 463 is not in contact with the convex mirror 410, and the convex mirror 410 is surrounded by the convex mirror protrusion 463. The convex mirror protrusion 463 overlaps the convex mirror 410 in a direction along the specific side surface 412.

The convex mirror holder 460 is fixed to the base member 451 in a state in which the main surface 464 opposite to the convex mirror 410 side is in contact with the main surface 452 of the base member 451. In the present embodiment, the convex mirror holder 460 is fixed to the base member 451 by an adhesive 453 arranged at the contact portion between the pair of side surfaces 465 facing each other and the main surface 452 of the base member 451 in the convex mirror holder 460. Here, the position of the adhesive 453 is not limited. For example, the adhesive 453 may be arranged between the main surface 464 of the convex mirror holder 460 and the main surface 452 of the base member 451.

A width 410W1 of the convex mirror 410 in a direction perpendicular to the specific side surface 412 of the convex mirror 410 is preferably 10 mm or more and 40 mm or less, but the width 410W1 is not limited. Further, a width 410W2 of the convex mirror 410 in a direction along an edge 412e on the reflection surface 411 side among edges of the specific side surface 412 of the convex mirror 410 is preferably 15 mm or more and 50 mm or less, but the width 410W2 is not limited.

FIG. 11 is a sectional view of the beam expander 400 at line XI-XI shown in FIG. 9 and is a sectional view of the beam expander 400 in a section across the concave mirror 420 and parallel to the focal line 420L. As shown in FIG. 11, the concave mirror holder 470 of the present embodiment is a plate-like member extending along a specific side surface 422 which is one of the two side surfaces 422 extending along the longitudinal direction of the concave mirror 420. Only one specific side surface 422 of the concave mirror 420 is fixed to the main surface 471 of the concave mirror holder 470 on the concave mirror 420 side by the adhesive 472. The adhesive 472 is separated into a plurality of adhesive portions. Since the adhesive 472 is arranged between the main surface 471 of the concave mirror holder 470 and the specific side surface 422 of the concave mirror 420, the main surface 471 and the specific side surface 422 are separated from each other, and a space is formed in a region where the adhesive 472 is not arranged between the main surface 471 and the specific side surface 422. Here, the adhesive 472 may not be separated into a plurality of adhesive portions.

The concave mirror holder 470 includes a concave mirror protrusion 473 protruding from the main surface 471 and arranged around the concave mirror 420. The concave mirror protrusion 473 is not in contact with the concave mirror 420, and the concave mirror 420 is surrounded by the concave mirror protrusion 473. The concave mirror protrusion 473 overlaps the concave mirror 420 in a direction along the specific side surface 422.

The concave mirror holder 470 is fixed to the base member 451 in a state in which the main surface 474 opposite to the concave mirror 420 side is in contact with the main surface 452 of the base member 451. In the present embodiment, the concave mirror holder 470 is mechanically fixed to the main surface 452 of the base member 451 by two bolts 454 sandwiching the concave mirror 420 in a direction parallel to the focal line 420L. The number and position of the bolts 454 are not limited. Further, the mechanical fixing is not limited to the fixing by the bolts 454. For example, the concave mirror holder 470 may be fixed to the main surface 452 of the base member 451 by a hook.

A width 420W1 of the concave mirror 420 in a direction perpendicular to the specific side surface 422 of the concave mirror 420 is preferably 10 mm or more and 40 mm or less, but the width 420W1 is not limited. Further, a width 420W2 of the concave mirror 420 in a direction along an edge 422e on the reflection surface 421 side among edges of the specific side surface 422 of the concave mirror 420 is preferably 15 mm or more and 50 mm or less, but the width 420W2 is not limited.

### 3.2 Operation

In the beam expander 400 of the present embodiment, similarly to the beam expander 400 of the comparative example, the laser light output from the window 331a of the chamber device CH3 is reflected in the order of the convex mirror 410 and the concave mirror 420, and the beam width of the laser light is expanded in the direction perpendicular to the direction in which the electrodes 332a, 332b face each other. Then, the laser light whose beam width is expanded is incident on the output coupling mirror 370. A part of the laser light incident on the output coupling mirror 370 is reflected by the output coupling mirror 370. The laser light reflected by the output coupling mirror 370 is reflected by the concave mirror 420 and the convex mirror 410 in this order, and the beam width of the laser light is reduced in the direction perpendicular to the direction in which the electrodes 332a, 332b face each other. The laser light whose beam width is reduced travels via the window 331a to the internal space of the housing 330 and is output from the window 331b. The light output from the window 331b is reflected by the rear mirror 371 and travels through the internal space of the housing 330 via the window 331b. Thus, the laser light reciprocates between the rear mirror 371 and the output coupling mirror 370, and is amplified every time it passes through the discharge space in the housing 330.

### 3.3 Effect

In the beam expander 400 of the present embodiment, similarly to the beam expander 400 of the comparative example, the energy density of the laser light incident on the output coupling mirror 370 can be reduced, and deterioration of the output coupling mirror 370 over time can be suppressed. In the beam expander 400 of the present embodiment, only one specific side surface 412 of the convex mirror 410 is fixed to the convex mirror holder 460 by the adhesive 462, and only one specific side surface 422 of the concave mirror 420 is fixed to the concave mirror holder 470 by the adhesive 472. Therefore, according to the gas laser device 100 of the present embodiment, compared with the case in which the back surface 413 of the convex mirror 410 is fixed to the convex mirror holder 460 by the adhesive 462, it is possible to suppress the laser light incident from the reflection surface 411 of the convex mirror 410 and transmitted through the convex mirror 410 from being radiated to the adhesive 462. Further, as compared with the case in which the back surface 423 of the concave mirror 420 is fixed to the concave mirror holder 470 by the adhesive 472, it is possible to suppress the laser light incident from the reflection surface 421 of the concave mirror 420 and transmitted through the concave mirror 420 from being radiated to the adhesive 472. Therefore, according to the gas laser device 100 of the present embodiment, deterioration of the adhesives 462, 472 due to the laser light can be suppressed, and deterioration of durability of the gas laser device 100 can be suppressed. In general, an adhesive shrinks when it is cured, but the thickness of the adhesive to be applied tends to vary depending on an application position due to manufacturing errors or the like, and thus an amount of shrinkage of the adhesive tends to vary depending on the application position of the adhesive. Therefore, when the back surface 413 of the convex mirror 410 is fixed by the adhesive 462, there is a fear that the reflection surface 411 is distorted due to the variation in the amount of shrinkage of the adhesive 462, and when the back surface 423 of the concave mirror 420 is fixed by the adhesive 472, there is a fear that the reflection surface 421 is distorted due to the variation in the amount of shrinkage of the adhesive 472. The distortion of the reflection surfaces 411, 421 in a direction as being close to a direction perpendicular to the reflection surfaces 411, 421 tends to have a larger influence on the beam profile of the laser light. In the beam expander 400 of the present embodiment, as described above, only one specific side surface 412 of the convex mirror 410 is fixed by the adhesive 462, and only one specific side surface 422 of the concave mirror 420 is fixed by the adhesive 472. Therefore, the shrinkage direction of the adhesive 462 may approach a direction parallel to the reflection surface 411 of the convex mirror 410, and the shrinkage direction of the adhesive 472 may approach a direction parallel to the reflection surface 421 of the concave mirror 420. Therefore, according to the gas laser device 100 of the present embodiment, the distortion of the reflection surface 411 in the direction perpendicular to the reflection surface 411 and the distortion of the reflection surface 421 in the direction perpendicular to the reflection surface 421 can be suppressed, and the influence on the beam profile of the laser light can be suppressed.

In the beam expander 400 of the present embodiment, the convex mirror holder 460 includes a convex mirror protrusion 463 protruding from the main surface 461 and arranged around the convex mirror 410. Therefore, according to the gas laser device 100 of the present embodiment, as compared with the case in which the convex mirror holder 460 does not include the convex mirror protrusion 463, it is possible to suppress the adhesive 462 from being deteriorated by being irradiated with scattered light. Here, the convex mirror holder 460 may not include the convex mirror protrusion 463.

In the beam expander 400 of the present embodiment, the convex mirror 410 is surrounded by the convex mirror protrusion 463. Therefore, according to the gas laser device 100 of the present embodiment, as compared with the case in which the convex mirror 410 is not surrounded by the convex mirror protrusion 463, it is possible to suppress the adhesive 462 from being deteriorated by being irradiated with the scattered light.

In the beam expander 400 of the present embodiment, the convex mirror protrusion 463 overlaps the convex mirror 410 in a direction along the specific side surface 412 of the convex mirror 410 fixed by the adhesive 462. Therefore, according to the gas laser device 100 of the present embodiment, as compared with the case in which the convex mirror protrusion 463 does not overlap the convex mirror 410 in the above-described direction, it is possible to suppress the adhesive 462 from being deteriorated by being irradiated with the scattered light. Here, the convex mirror protrusion 463 may not overlap the convex mirror 410 in the above-described direction.

In the beam expander 400 of the present embodiment, the concave mirror holder 470 includes a concave mirror protrusion 473 protruding from the main surface 471 and arranged around the concave mirror 420. Therefore, according to the gas laser device 100 of the present embodiment, as compared with the case in which the concave mirror holder 470 does not include the concave mirror protrusion 473, it is possible to suppress the adhesive 472 from being deteriorated by being irradiated with the scattered light. Here, the concave mirror holder 470 may not include the concave mirror protrusion 473.

In the beam expander 400 of the present embodiment, the concave mirror 420 is surrounded by the concave mirror protrusion 473. Therefore, according to the gas laser device 100 of the present embodiment, as compared with the case in which the concave mirror 420 is not surrounded by the concave mirror protrusion 473, it is possible to suppress the adhesive 472 from being deteriorated by being irradiated with the scattered light.

In the beam expander 400 of the present embodiment, the concave mirror protrusion 473 overlaps the concave mirror 420 in a direction along the specific side surface 422 fixed by the adhesive 472 in the concave mirror 420. Therefore, according to the gas laser device 100 of the present embodiment, as compared with the case in which the concave mirror protrusion 473 does not overlap the concave mirror 420 in the above-described direction, it is possible to suppress the adhesive 472 from being deteriorated by being irradiated with the scattered light. Here, the concave mirror protrusion 473 may not overlap the concave mirror 420 in the above-described direction.

In the present embodiment, the convex mirror 410 is surrounded by the convex mirror protrusion 463 in a non-contact manner with the convex mirror protrusion 463, and the concave mirror 420 is surrounded by the concave mirror protrusion 473 in a non-contact manner with the concave mirror protrusion 473. However, the convex mirror protrusion 463 and the convex mirror 410 may be in contact with each other, and the concave mirror protrusion 473 and the concave mirror 420 may be in contact with each other. However, at least one set of the convex mirror protrusion 463 and the convex mirror 410, and the concave mirror protrusion 473 and the concave mirror 420 may be in a non-contact manner. Further, the convex mirror 410 may not be surrounded by the convex mirror protrusion 463, and the concave mirror 420 may not be surrounded by the concave mirror protrusion 473. However, it is preferable that at least one of the convex mirror 410 and the concave mirror 420 is surrounded by the corresponding protrusion among the convex mirror protrusion 463 and the concave mirror protrusion 473. Here, the protrusion corresponding to the convex mirror 410 is the convex mirror protrusion 463, and the protrusion corresponding to the concave mirror 420 is the concave mirror protrusion 473.

In the present embodiment, only the specific side surface 412 extending along the longitudinal direction of the convex mirror 410 is fixed by the adhesive 462, and only the specific side surface 422 extending along the longitudinal direction of the concave mirror 420 is fixed by the adhesive 472. However, one side surface 412 of the convex mirror 410 fixed by the adhesive 462 and one side surface 422 of the concave mirror 420 fixed by the adhesive 472 are not limited to the specific side surfaces 412, 422 in the above description. For example, only one side surface 412 extending along the transverse direction of the convex mirror 410 may be fixed by the adhesive 462, and only one side surface 422 extending along the transverse direction of the concave mirror 420 may be fixed by the adhesive 472.

In the present embodiment, the holding portion 450 includes the base member 451, the convex mirror holder 460, and the concave mirror holder 470. However, the holding portion 450 is not limited as long as only one side surface 412 of the convex mirror 410 is fixed by the adhesive 462 and only one side surface 422 of the concave mirror 420 is fixed by the adhesive 472. For example, the holding portion 450 may not include the convex mirror holder 460 and the concave mirror holder 470. In this case, for example, only one side surface 412 of the convex mirror 410 is fixed to the main surface 452 of the base member 451 by the adhesive 462, and only one side surface 422 of the concave mirror 420 is fixed to the main surface 452 of the base member 451 by the adhesive 472. In this case, the base member 451 may include at least one of the convex mirror protrusion 463 and the concave mirror protrusion 473.

In the present embodiment, the convex mirror holder 460 is fixed to the main surface 452 of the base member 451 by the adhesive 453, and the concave mirror holder 470 is mechanically fixed to the main surface 452 of the base member 451. However, the method of fixing the convex mirror holder 460 and the concave mirror holder 470 to the base member 451 is not limited. For example, at least one of the convex mirror holder 460 and the concave mirror holder 470 may be fixed to the base member 451 by an adhesive. Further, one of the convex mirror holder 460 and the concave mirror holder 470 may be fixed to the base member 451 by an adhesive, and the other may be mechanically fixed to the base member 451.

### 4. Description of Gas Laser Device of Second Embodiment

Next, the gas laser device 100 of a second embodiment will be described. Any component same as that described above is denoted by an identical reference sign, and duplicate description thereof is omitted unless specific description is needed. Further, in some drawings, a part of a member may be omitted or simplified for easy viewing.

### 4.1 Configuration

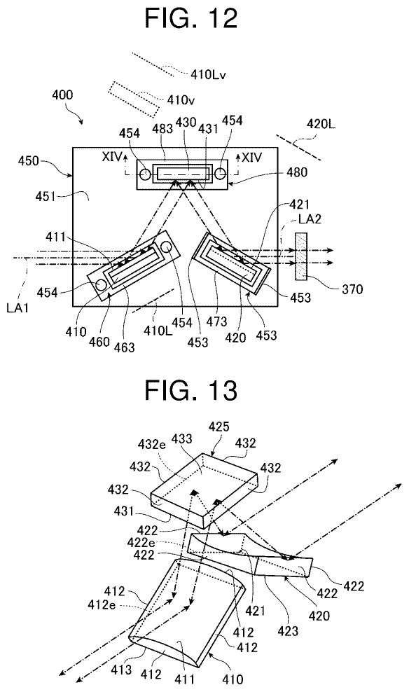

FIG. 12 is a schematic view showing a schematic configuration example of the beam expander 400 of the present embodiment in a similar manner to FIG. 3. As shown in FIG. 12, the beam expander 400 of the present embodiment is mainly different from the beam expander 400 of the first embodiment in that the beam expander 400 further includes a planar mirror 430, and that the holding portion 450 further includes a planar mirror holder 480.

FIG. 13 is a perspective view showing the convex mirror 410, the planar mirror 430, and the concave mirror 420 of the present embodiment in a similar manner to FIG. 4. As shown in FIGS. 12 and 13, in the present embodiment, the convex mirror 410 reflects the laser light from the chamber device CH3 toward the planar mirror 430. The planar mirror 430 is a plate-like member, and includes a planar reflection surface 431 that reflects light, a plurality of side surfaces 432, and a back surface 433 that is located on the back side of the reflection surface 431 and faces the reflection surface 431. The reflection surface 431 of the planar mirror 430 reflects the laser light, toward the concave mirror 420, reflected by the convex mirror 410. The concave mirror 420 reflects the laser light, toward the output coupling mirror 370, reflected by the planar mirror 430. Further, the concave mirror 420 reflects the laser light, toward the planar mirror 430, reflected by the output coupling mirror 370, the planar mirror 430 reflects the laser light, toward the convex mirror 410, reflected by the concave mirror 420, and the convex mirror 410 reflects the laser light, toward the chamber device CH3, reflected by the planar mirror 430.

The focal line 410L of the convex mirror 410 is included in the plane including the optical axis LA1 of the laser light and extending in the direction in which the electrodes 332a, 332b face each other, and is inclined so as to approach the electrode 332a as the distance from the chamber device CH3 increases. Further, the focal line 420L of the concave mirror 420 is included in the plane including the optical axis LA1 of the laser light and the focal line 410L, and is inclined so as to approach the electrode 332b as the distance from the chamber device CH3 increases. Then, a focal line 410Lv of a virtual image 410v of the convex mirror 410 formed by the reflection surface 431 of the planar mirror 430 and the focal line 420L of the concave mirror 420 are located on the same straight line. Further, the optical axis LA1 of the laser light from the chamber device CH3 toward the convex mirror 410 and an optical axis LA2 of the laser light from the concave mirror 420 toward the output coupling mirror 370 are located on the same straight line. That is, the positions of the convex mirror 410, the planar mirror 430, and the concave mirror 420 are adjusted as described above. In FIG. 12, the virtual image 410v and the focal line 410Lv of the virtual image 410v are indicated by broken lines.

In the present embodiment, the shape of the planar mirror 430 when the reflection surface 431 is viewed from the front is a rectangle elongated in a direction parallel to the optical axis LA1 of the laser light from the chamber device CH3. Thus, the planar mirror 430 includes four planar side surfaces 432. The shape of the planar mirror 430 and the number of the side surfaces 432 are not limited. For example, the shape of the planar mirror 430 may be a rectangle elongated in a direction perpendicular to the optical axis LA1.

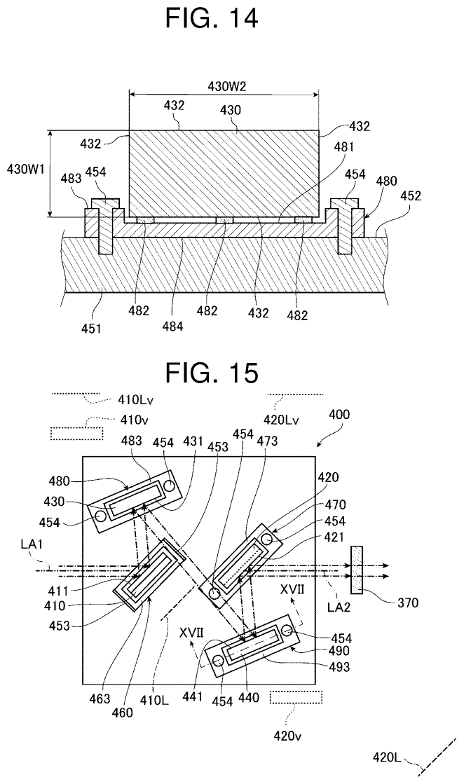

FIG. 14 is a sectional view of the beam expander 400 at line XIV-XIV shown in FIG. 12 and is a sectional view of the beam expander 400 in a section across the planar mirror 430 and parallel to the reflection surface 431. As shown in FIG. 14, the planar mirror holder 480 of the present embodiment is a plate-like member extending along a specific side surface 432 which is one of two side surfaces 432 extending along the longitudinal direction of the planar mirror 430. Only one specific side surface 432 of the planar mirror 430 is fixed to a main surface 481 of the planar mirror holder 480 on the planar mirror 430 side by an adhesive 482. The adhesive 482 is separated into a plurality of adhesive portions. Since the adhesive 482 is arranged between the main surface 481 of the planar mirror holder 480 and the specific side surface 432 of the planar mirror 430, the main surface 481 and the specific side surface 432 are separated from each other, and a space is formed in a region where the adhesive 482 is not arranged between the main surface 481 and the specific side surface 432. The adhesive 482 may be, for example, an adhesive similar to the adhesive 462. Here, the adhesive 482 may not be separated into a plurality of adhesive portions.

The planar mirror holder 480 includes a planar mirror protrusion 483 protruding from the main surface 481 and arranged around the planar mirror 430. The planar mirror protrusion 483 is not in contact with the planar mirror 430, and the planar mirror 430 is surrounded by the planar mirror protrusion 483. Further, the planar mirror protrusion 483 overlaps the planar mirror 430 in a direction along the specific side surface 432.

The planar mirror holder 480 is fixed to the base member 451 in a state in which the main surface 484 opposite to the planar mirror 430 side is in contact with the main surface 452 of the base member 451. In the present embodiment, similarly to the concave mirror holder 470 of the first embodiment, the concave mirror holder 470 is mechanically fixed to the main surface 452 of the base member 451 by the two bolts 454. The number and position of the bolts 454 are not limited. Further, the mechanical fixing is not limited to the fixing by the bolts 454. For example, the planar mirror holder 480 may be fixed to the main surface 452 of the base member 451 by a hook.

A width 430W1 of the planar mirror 430 in a direction perpendicular to the specific side surface 432 of the planar mirror 430 is preferably 10 mm or more and 40 mm or less, but the width 430W1 is not limited. Further, a width 430W2 of the planar mirror 430 in a direction along the edge 432e on the reflection surface 431 side among edges of the specific side surface 432 of the planar mirror 430 is preferably 15 mm or more and 50 mm or less, but the width 430W2 is not limited.

Similarly to the concave mirror holder 470 of the first embodiment, the convex mirror holder 460 of the present embodiment is mechanically fixed to the main surface 452 of the base member 451 by the two bolts 454. Here, the number and position of the bolts 454 are not limited. Further, the mechanical fixing is not limited to the fixing by the bolts 454. For example, the convex mirror holder 460 may be fixed to the main surface 452 of the base member 451 by a hook.

Similarly to the convex mirror holder 460 of the first embodiment, the concave mirror holder 470 of the present embodiment is fixed to the base member 451 by the adhesive 453. Here, the position of the adhesive 453 is not limited. For example, the adhesive 453 may be arranged between the main surface 474 of the concave mirror holder 470 and the main surface 452 of the base member 451.

### 4.2 Operation

Similarly to the first embodiment, the laser light output from the window 331a is reflected by the convex mirror 410, and the beam width of the laser light is expanded in the direction perpendicular to the direction in which the electrodes 332a, 332b face each other. The laser light whose beam width is expanded is reflected by the reflection surface 431 of the planar mirror 430 toward the concave mirror 420. As described above, the focal line 410Lv of the virtual image 410v and the focal line 420L of the concave mirror 420 are located on the same straight line. Therefore, the laser light reflected by the planar mirror 430 is reflected by the concave mirror 420 to be collimated so that the expanded beam width becomes constant, and the collimated laser light is incident on the output coupling mirror 370.

Further, the laser light reflected by the output coupling mirror 370 is reflected by the concave mirror 420 toward the planar mirror 430. The beam width of the laser light is reduced in the direction perpendicular to the direction in which the electrodes 332a, 332b face each other. The laser light whose beam width is reduced is reflected by the planar mirror 430 toward the convex mirror 410, and the laser light reflected by the planar mirror 430 is reflected by the convex mirror 410 toward the window 331a. The laser light is collimated so that the reduced beam width becomes constant, and is returned to the internal space of the housing 330 via the window 331a.

### 4.3 Effect

According to the gas laser device 100 of the present embodiment, similarly to the gas laser device 100 of the first embodiment, it is possible to reduce the energy density of the laser light incident on the output coupling mirror 370 and suppress the deterioration of the output coupling mirror 370 over time. In the beam expander 400 of the present embodiment, only one specific side surface 432 of the planar mirror 430 is fixed to the planar mirror holder 480 by the adhesive 472. Therefore, according to the gas laser device 100 of the present embodiment, as compared with the case in which the back surface 433 of the planar mirror 430 is fixed to the planar mirror holder 480 by the adhesive 482, it is possible to suppress the laser light incident from the reflection surface 431 of the planar mirror 430 and transmitted through the planar mirror 430 from being radiated to the adhesive 482. Therefore, according to the gas laser device 100 of the present embodiment, deterioration of the adhesive 482 due to the laser light can be suppressed, and deterioration of durability of the gas laser device 100 can be suppressed. Further, according to the gas laser device 100 of the present embodiment, similarly to the convex mirror 410 and the concave mirror 420 of the first embodiment, the distortion of the reflection surface 431 in a direction perpendicular to the reflection surface 431 can be suppressed, and the influence on the beam profile of the laser light can be suppressed.

In the beam expander 400 of the present embodiment, the planar mirror holder 480 includes a planar mirror protrusion 483 protruding from the main surface 481 and arranged around the planar mirror 430. Therefore, according to the gas laser device 100 of the present embodiment, as compared with the case in which the planar mirror holder 480 does not include the planar mirror protrusion 483, it is possible to suppress deterioration of the adhesive 482 by being irradiated with the scattered light. Here, the planar mirror holder 480 may not include the planar mirror protrusion 483.

In the beam expander 400 of the present embodiment, the planar mirror 430 is surrounded by the planar mirror protrusion 483. Therefore, according to the gas laser device 100 of the present embodiment, as compared with the case in which the planar mirror 430 is not surrounded by the planar mirror protrusion 483, it is possible to suppress deterioration of the adhesive 482 by being irradiated with the scattered light.

In the beam expander 400 of the present embodiment, the planar mirror protrusion 483 overlaps the planar mirror 430 in a direction along the specific side surface 432 fixed by the adhesive 482 in the planar mirror 430. Therefore, according to the gas laser device 100 of the present embodiment, as compared with the case in which the planar mirror protrusion 483 does not overlap the planar mirror 430 in the above-described direction, it is possible to suppress deterioration of the adhesive 482 by being irradiated with the scattered light. Here, the planar mirror protrusion 483 may not overlap the planar mirror 430 in the above-described direction.

In the present embodiment, the planar mirror 430 is surrounded by the planar mirror protrusion 483 in a non-contact manner with the planar mirror protrusion 483, but the planar mirror protrusion 483 and the planar mirror 430 may be in contact with each other. However, at least one set of the convex mirror protrusion 463 and the convex mirror 410, the concave mirror protrusion 473 and the concave mirror 420, and the planar mirror protrusion 483 and the planar mirror 430 may be in a non-contact manner. At least one of the convex mirror 410, the concave mirror 420, and the planar mirror 430 is preferably surrounded by the corresponding protrusion among the convex mirror protrusion 463, the concave mirror protrusion 473, and the planar mirror protrusion 483. Here, the protrusion corresponding to the convex mirror 410 is the convex mirror protrusion 463, the protrusion corresponding to the concave mirror 420 is the concave mirror protrusion 473, and the protrusion corresponding to the planar mirror 430 is the planar mirror protrusion 483.

In the present embodiment, only the specific side surface 432 extending along the longitudinal direction of the planar mirror 430 is fixed by the adhesive 482. However, one side surface 432 of the planar mirror 430 fixed by the adhesive 482 is not limited to the specific side surface 432 in the above description. For example, only one side surface 432 extending along the transverse direction of the planar mirror 430 may be fixed by the adhesive 482.

In the present embodiment, the holding portion 450 includes the base member 451, the convex mirror holder 460, the concave mirror holder 470, and the planar mirror holder 480. However, the holding portion 450 is not limited as long as only one side surface 412 of the convex mirror 410 is fixed by the adhesive 462, only one side surface 422 of the concave mirror 420 is fixed by the adhesive 472, and only one side surface 432 of the planar mirror 430 is fixed by the adhesive 482. For example, the holding portion 450 may not include the planar mirror holder 480. In this case, for example, only one side surface 432 of the planar mirror 430 is fixed to the main surface 452 of the base member 451 by the adhesive 482. In this case, the base member 451 may include the planar mirror protrusion 483.

In the present embodiment, the convex mirror holder 460 and the planar mirror holder 480 are mechanically fixed to the main surface 452 of the base member 451, and the concave mirror holder 470 is fixed to the main surface 452 of the base member 451 by the adhesive 453. However, the method of fixing the convex mirror holder 460, the concave mirror holder 470, and the planar mirror holder 480 to the base member 451 is not limited. For example, at least one of the convex mirror holder 460 and the concave mirror holder 470 may be fixed to the base member 451 by an adhesive. Further, one of the convex mirror holder 460 and the concave mirror holder 470 may be fixed to the base member 451 by an adhesive, and the other may be mechanically fixed to the base member 451. Further, the planar mirror holder 480 may be fixed to the base member 451 by an adhesive.

In the present embodiment, the focal line 410Lv of the virtual image 410v and the focal line 420L are located on the same straight line, but the focal line 410Lv and the focal line 420Lv may not be located on the same straight line.

In the present embodiment, the optical axis LA1 of the laser light from the chamber device CH3 toward the convex mirror 410 and the optical axis LA2 of the laser light from the concave mirror 420 toward the output coupling mirror 370 are located on the same straight line. Therefore, for example, the beam expander 400 may be arranged in the conventional amplifier 160 without changing the designed positions of the chamber device CH3 and the output coupling mirror 370. Here, the optical axis LA1 and the optical axis LA2 may not be located on the same straight line.

### 5. Description of Gas Laser Device of Third Embodiment

Next, the gas laser device 100 of a third embodiment will be described. Any component same as that described above is denoted by an identical reference sign, and duplicate description thereof is omitted unless specific description is needed. Further, in some drawings, a part of a member may be omitted or simplified for easy viewing.

### 5.1 Configuration

FIG. 15 is a schematic view showing a schematic configuration example of the beam expander 400 of the present embodiment in a similar manner to FIG. 3. As shown in FIG. 15, the beam expander 400 of the present embodiment is mainly different from the beam expander 400 of the second embodiment in that the beam expander 400 further includes a planar mirror 440 and that the holding portion 450 further includes a planar mirror holder 490.

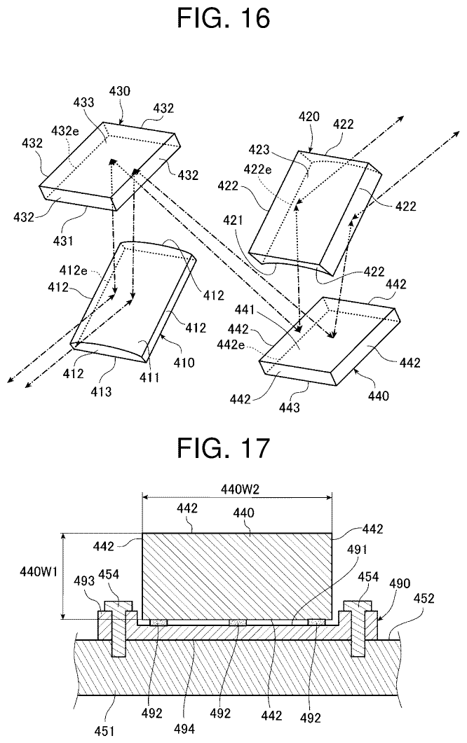

FIG. 16 is a perspective view showing the convex mirror 410, the two planar mirrors 430, 440, and the concave mirror 420 of the present embodiment in a similar manner to FIG. 4. Hereinafter, the planar mirror 430 is referred to as a first planar mirror, the planar mirror 440 is referred to as a second planar mirror, the planar mirror holder 480 is referred to as a first planar mirror holder, the planar mirror holder 490 is referred to as a second planar mirror holder, and the planar mirror protrusion 483 is referred to as a first planar mirror protrusion.

In the present embodiment, the convex mirror 410 reflects the laser light from the chamber device CH3 toward the first planar mirror 430. The first planar mirror 430 reflects the laser light, toward the second planar mirror 440, reflected by the convex mirror 410. The second planar mirror 440 is a plate-like member, and includes a flat reflection surface 441 that reflects light, a plurality of side surfaces 442, and a back surface 443 that is located on the back side of the reflection surface 441 and faces the reflection surface 441. The reflection surface 441 of the second planar mirror 440 reflects the laser light, toward the concave mirror 420, reflected by the first planar mirror 430. The concave mirror 420 reflects the laser light, toward the output coupling mirror 370, reflected by the second planar mirror 440. The concave mirror 420 reflects the laser light, toward the second planar mirror 440, reflected by the output coupling mirror 370, and the second planar mirror 440 reflects the laser light, toward the first planar mirror 430, reflected by the concave mirror 420. The first planar mirror 430 reflects the laser light, toward the convex mirror 410, reflected by the second planar mirror 440, and the convex mirror 410 reflects the laser light, toward the chamber device CH3, reflected by the first planar mirror 430.

The focal line 410L of the convex mirror 410 is included in the plane including the optical axis LA1 of the laser light and extending in the direction in which the electrodes 332a, 332b face each other, and is inclined so as to approach the electrode 332a as the distance from the chamber device CH3 increases. Further, the focal line 420L of the concave mirror 420 is included in the plane including the optical axis LA1 of the laser light and the focal line 410L, and is inclined so as to approach the electrode 332b as the distance from the chamber device CH3 increases. Then, the focal line 410Lv of the virtual image 410v of the convex mirror 410 formed by the reflection surface 431 of the first planar mirror 430 and the focal line 420Lv of the virtual image 420v of the concave mirror 420 formed by the reflection surface 441 of the second planar mirror 440 are located on the same straight line. Further, the optical axis LA1 of the laser light from the chamber device CH3 toward the convex mirror 410 and the optical axis LA2 of the laser light from the concave mirror 420 toward the output coupling mirror 370 are located on the same straight line. That is, the positions of the convex mirror 410, the first planar mirror 430, the second planar mirror 440, and the concave mirror 420 are adjusted as described above. In FIG. 15, the virtual image 410v, the focal line 410Lv of the virtual image 410v, the virtual image 420v, and the focal line 420Lv of the virtual image 420v are indicated by broken lines.

In the present embodiment, the shape of the second planar mirror 440 when the reflection surface 441 is viewed from the front is a rectangle elongated in a direction parallel to the optical axis LA1 of the laser light from the chamber device CH3. Thus, the second planar mirror 440 includes four planar side surfaces 442. The shape of the second planar mirror 440 and the number of side surfaces 442 are not limited. For example, the shape of the second planar mirror 440 may be a rectangle elongated in a direction perpendicular to the optical axis LA1.

FIG. 17 is a sectional view of the beam expander 400 at line XVII-XVII shown in FIG. 15 and is a sectional view of the beam expander 400 in a section across the second planar mirror 440 and parallel to the reflection surface 441. As shown in FIG. 17, the second planar mirror holder 490 of the present embodiment is a plate-like member extending along a specific side surface 442 which is one of two side surfaces 442 extending along the longitudinal direction of the second planar mirror 440. Only one specific side surface 442 of the second planar mirror 440 is fixed to the main surface 491 of the second planar mirror holder 490 on the second planar mirror 440 side by an adhesive 492. The adhesive 492 is separated into a plurality of adhesive portions. Since the adhesive 492 is arranged between the main surface 491 of the second planar mirror holder 490 and the specific side surface 442 of the second planar mirror 440, the main surface 491 and the specific side surface 442 are separated from each other, and a space is formed in a region where the adhesive 492 is not arranged between the main surface 491 and the specific side surface 442. The adhesive 492 may be, for example, an adhesive similar to the adhesive 462. Here, the adhesive 492 may not be separated into a plurality of adhesive portions.

The second planar mirror holder 490 includes a second planar mirror protrusion 493 protruding from the main surface 491 and arranged around the second planar mirror 440. The second planar mirror protrusion 493 is not in contact with the second planar mirror 440, and the second planar mirror 440 is surrounded by the second planar mirror protrusion 493. Further, the second planar mirror protrusion 493 overlaps the second planar mirror 440 in a direction along the specific side surface 442.

The second planar mirror holder 490 is fixed to the base member 451 in a state in which the main surface 494 opposite to the second planar mirror 440 side is in contact with the main surface 452 of the base member 451. In the present embodiment, similarly to the concave mirror holder 470 of the first embodiment, the concave mirror holder 470 is mechanically fixed to the main surface 452 of the base member 451 by the two bolts 454. Here, the number and position of the bolts 454 are not limited. Further, the mechanical fixing is not limited to the fixing by the bolts 454. For example, the second planar mirror holder 490 may be fixed to the main surface 452 of the base member 451 by a hook.

A width 440W1 of the second planar mirror 440 in a direction perpendicular to the specific side surface 442 of the second planar mirror 440 is preferably 10 mm or more and 40 mm or less, but the width 440W1 is not limited. Further, a width 440W2 of the second planar mirror 440 in a direction along the edge 442e on the reflection surface 441 side among edges of the specific side surface 442 of the second planar mirror 440 is preferably 15 mm or more and 50 mm or less, but the width 440W2 is not limited.

Similarly to the convex mirror holder 460 of the first embodiment, the convex mirror holder 460 of the present embodiment is fixed to the base member 451 by the adhesive 453. Here, the position of the adhesive 453 is not limited. For example, the adhesive 453 may be arranged between the main surface 464 of the convex mirror holder 460 and the main surface 452 of the base member 451.

Similarly to the concave mirror holder 470 of the first embodiment, each of the concave mirror holder 470, the first planar mirror holder 480, and the second planar mirror holder 490 of the present embodiment is mechanically fixed to the main surface 452 of the base member 451 by the two bolts 454. Here, the number and position of the bolts 454 are not limited. Further, the mechanical fixing is not limited to the fixing by the bolts 454. For example, the concave mirror holder 470, the first planar mirror holder 480, and the second planar mirror holder 490 may be fixed to the main surface 452 of the base member 451 by hooks.

### 5.2 Operation

Similarly to the second embodiment, the laser light output from the window 331a is reflected by the convex mirror 410, and the beam width of the laser light is expanded in the direction perpendicular to the direction in which the electrodes 332a, 332b face each other. The laser light whose beam width is expanded is reflected by the first planar mirror 430 toward the second planar mirror 440, and the laser light reflected by the first planar mirror 430 is reflected by the reflection surface 441 of the second planar mirror 440 toward the concave mirror 420. As described above, the focal line 410Lv of the virtual image 410v and the focal line 420Lv of the virtual image 420v are located on the same straight line. Therefore, the laser light reflected by the second planar mirror 440 is reflected by the concave mirror 420 to be collimated so that the expanded beam width becomes constant, and the collimated laser light is incident on the output coupling mirror 370.

Further, the laser light reflected by the output coupling mirror 370 is reflected by the concave mirror 420 toward the second planar mirror 440. The beam width of the laser light is reduced in the direction perpendicular to the direction in which the electrodes 332a, 332b face each other. The laser light whose beam width is reduced is reflected by the second planar mirror 440 toward the first planar mirror 430, and the laser light reflected by the second planar mirror 440 is reflected by the first planar mirror 430 toward the concave mirror 420. The laser light reflected by the first planar mirror 430 is reflected by the convex mirror 410 toward the window 331a. The laser light is collimated so that the reduced beam width becomes constant, and is returned to the internal space of the housing 330 via the window 331a.

### 5.3 Effect

According to the gas laser device 100 of the present embodiment, similarly to the gas laser device 100 of the first embodiment, it is possible to reduce the energy density of the laser light incident on the output coupling mirror 370 and suppress the deterioration of the output coupling mirror 370 over time. In the beam expander 400 of the present embodiment, only one specific side surface 442 of the second planar mirror 440 is fixed to the second planar mirror holder 490 by the adhesive 492. Therefore, according to the gas laser device 100 of the present embodiment, as compared with the case in which the back surface 443 of the second planar mirror 440 is fixed to the planar mirror holder 490 by the adhesive 492, it is possible to suppress the laser light incident from the reflection surface 441 of the second planar mirror 440 and transmitted through the second planar mirror 440 from being radiated to the adhesive 492. Therefore, according to the gas laser device 100 of the present embodiment, deterioration of the adhesive 492 due to the laser light can be suppressed, and deterioration of durability of the gas laser device 100 can be suppressed. Further, according to the gas laser device 100 of the present embodiment, similarly to the convex mirror 410 and the concave mirror 420 of the first embodiment, the distortion of the reflection surface 441 in a direction perpendicular to the reflection surface 441 can be suppressed, and the influence on the beam profile of the laser light can be suppressed.

In the beam expander 400 of the present embodiment, the second planar mirror holder 490 includes a second planar mirror protrusion 493 protruding from the main surface 491 and arranged around the second planar mirror 440. Therefore, according to the gas laser device 100 of the present embodiment, as compared with the case in which the second planar mirror holder 490 does not include the second planar mirror protrusion 493, it is possible to suppress deterioration of the adhesive 492 by being irradiated with the scattered light. Here, the second planar mirror holder 490 may not include the second planar mirror protrusion 493.

In the beam expander 400 of the present embodiment, the second planar mirror 440 is surrounded by the second planar mirror protrusion 493. Therefore, according to the gas laser device 100 of the present embodiment, as compared with the case in which the second planar mirror 440 is not surrounded by the second planar mirror protrusion 493, it is possible to suppress deterioration of the adhesive 492 by being irradiated with the scattered light.

In the beam expander 400 of the present embodiment, the second planar mirror protrusion 493 overlaps the second planar mirror 440 in a direction along the specific side surface 442 fixed by the adhesive 492 in the second planar mirror 440. Therefore, according to the gas laser device 100 of the present embodiment, as compared with the case in which the second planar mirror protrusion 493 does not overlap the second planar mirror 440 in the above-described direction, it is possible to suppress deterioration of the adhesive 492 by being irradiated with the scattered light. Here, the planar mirror protrusion 483 may not overlap the second planar mirror 440 in the above-described direction.

In the present embodiment, the second planar mirror 440 is surrounded by the second planar mirror protrusion 493 in a non-contact manner with the second planar mirror protrusion 493, but the second planar mirror protrusion 493 and the second planar mirror 440 may be in contact with each other. However, at least one set of the convex mirror protrusion 463 and the convex mirror 410, the concave mirror protrusion 473 and the concave mirror 420, the first planar mirror protrusion 483 and the first planar mirror 430, and the second planar mirror protrusion 493 and the second planar mirror 440 may be in a non-contact manner. Further, at least one of the convex mirror 410, the concave mirror 420, the first planar mirror 430, and the second planar mirror 440 is preferably surrounded by the corresponding protrusion among the convex mirror protrusion 463, the concave mirror protrusion 473, the first planar mirror protrusion 483, and the second planar mirror protrusion 493. Here, the protrusion corresponding to the convex mirror 410 is the convex mirror protrusion 463, the protrusion corresponding to the concave mirror 420 is the concave mirror protrusion 473, the protrusion corresponding to the first planar mirror 430 is the first planar mirror protrusion 483, and the protrusion corresponding to the second planar mirror 440 is the second planar mirror protrusion 493.

In the present embodiment, only the specific side surface 442 extending along the longitudinal direction of the second planar mirror 440 is fixed by the adhesive 492. However, one side surface 442 of the second planar mirror 440 fixed by the adhesive 492 is not limited to the specific side surface 442 in the above description. For example, only one side surface 442 extending along the transverse direction of the second planar mirror 440 may be fixed by the adhesive 492.

In the present embodiment, the holding portion 450 includes the base member 451, the convex mirror holder 460, the concave mirror holder 470, the first planar mirror holder 480, and the second planar mirror holder 490. However, the holding portion 450 is not limited as long as only one side surface 412 of the convex mirror 410 is fixed by the adhesive 462, only one side surface 422 of the concave mirror 420 is fixed by the adhesive 472, only one side surface 432 of the first planar mirror 430 is fixed by the adhesive 492, and only one side surface 442 of the second planar mirror 440 is fixed by the adhesive 492. For example, the holding portion 450 may not include the second planar mirror holder 490. In this case, for example, only one side surface 442 of the second planar mirror 440 may be fixed to the main surface 452 of the base member 451 by the adhesive 492, and the base member 451 may include the second planar mirror protrusion 493.

In the present embodiment, the convex mirror holder 460 is fixed to the main surface 452 of the base member 451 by the adhesive 453, and the concave mirror holder 470, the first planar mirror holder 480, and the second planar mirror holder 490 are mechanically fixed to the main surface 452 of the base member 451. However, the method of fixing the convex mirror holder 460, the concave mirror holder 470, the first planar mirror holder 480, and the second planar mirror holder 490 to the base member 451 is not limited. For example, at least one of the convex mirror holder 460 and the concave mirror holder 470 may be fixed to the base member 451 by an adhesive. Further, one of the convex mirror holder 460 and the concave mirror holder 470 may be fixed to the base member 451 by an adhesive, and the other may be mechanically fixed to the base member 451. Further, the second planar mirror holder 490 may be fixed to the base member 451 by an adhesive.

In the amplifier 160 of the present embodiment, the members that reflect the laser light from the chamber device CH3 to the output coupling mirror 370 are only the convex mirror 410, the first planar mirror 430, the second planar mirror 440, and the concave mirror 420, and the number of times the laser light is reflected is four. Therefore, according to the gas laser device 100 of the present embodiment, the laser light from the chamber device CH3 toward the convex mirror 410 and the laser light from the concave mirror 420 toward the output coupling mirror 370 can be prevented from being reversed by reflection in the beam profile.

In the present embodiment, the focal line 410Lv of the virtual image 410v and the focal line 420Lv of the virtual image 420v are located on the same straight line, but the focal line 410Lv and the focal line 420Lv may not be located on the same straight line.

In the present embodiment, the optical axis LA1 of the laser light from the chamber device CH3 toward the convex mirror 410 and the optical axis LA2 of the laser light from the concave mirror 420 toward the output coupling mirror 370 are located on the same straight line. Therefore, for example, the beam expander 400 may be arranged in the conventional amplifier 160 without changing the designed positions of the chamber device CH3 and the output coupling mirror 370. Here, the optical axis LA1 and the optical axis LA2 may not be located on the same straight line.

Although the above embodiments have been described as examples, the present disclosure is not limited thereto, and can be modified as appropriate.

In each of the above-described embodiments, description has been performed on the example in which the convex mirror 410 reflects the laser light to expand the beam width of the laser light output from the chamber device CH3 in the direction perpendicular to the direction in which the electrodes 332a, 332b face each other. However, the direction in which the beam width is expanded by the convex mirror 410 is not limited. For example, the direction of the beam width expanded by the convex mirror 410 may be the direction in which the electrodes 332a, 332b face each other.

Further, in the above embodiments, the gas laser device 100 including the laser oscillator 130 and the amplifier 160 has been described. However, the gas laser device 100 may not include the amplifier 160. In this case, for example, the beam expander 400 is arranged between the chamber device CH1 and the output coupling mirror 70, and the laser light output from the window 31a of the chamber device CH3 is incident on the convex mirror 410.

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious to those skilled in the art that the embodiments of the present disclosure would be appropriately combined. The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more”. Further, “at least one of A, B, and C” should be interpreted to mean any of A, B, C, A+B, A+C, B+C, and A+B+C as well as to include combinations of the any thereof and any other than A, B, and C.

What is claimed is:

1. A gas laser device comprising:
a chamber device including a pair of discharge electrodes facing each other and arranged at an internal space thereof in which a laser gas is filled, and configured to output light generated from the laser gas by a voltage being applied between the pair of discharge electrodes;
a resonator configured to cause the light output from the chamber device to resonate between both sides sandwiching the chamber device; and
a beam expander,
the resonator including an output coupling mirror arranged on one side of the sides sandwiching the chamber device, and being configured to cause a part of the light output from the chamber device to be transmitted therethrough, and another part of the light output from the chamber device to be reflected to return into the chamber device, and
the beam expander being arranged between the chamber device and the output coupling mirror, and including:
a holding portion;
a convex mirror including a reflection surface reflecting the light output from the chamber device to expand a beam width of the light, and a plurality of side surfaces with only one side surface among the plurality of side surfaces fixed to the holding portion by an adhesive; and
a concave mirror including a reflection surface reflecting the light reflected by the convex mirror toward the output coupling mirror so as to collimate the light so that the expanded beam width of the light becomes constant, and a plurality of side surfaces with only one side surface among the plurality of side surfaces fixed to the holding portion by an adhesive.

2. The gas laser device according to claim 1,
wherein the holding portion includes a convex mirror protrusion protruding from a surface to which the one side surface of the convex mirror is fixed by the adhesive and arranged around the convex mirror, and a concave mirror protrusion protruding from a surface to which the one side surface of the concave mirror is fixed by the adhesive and arranged around the concave mirror.

3. The gas laser device according to claim 2,
wherein at least one set of the convex mirror protrusion and the convex mirror, and the concave mirror protrusion and the concave mirror is in a non-contact manner.

4. The gas laser device according to claim 3,
wherein at least one of the convex mirror and the concave mirror is surrounded by a corresponding protrusion among the convex mirror protrusion and the concave mirror protrusion.

5. The gas laser device according to claim 1,
wherein the holding portion includes a plate-shaped base member extending in a direction parallel to an optical axis of the light traveling from the chamber device toward the convex mirror, a convex mirror holder to which the one side surface of the convex mirror is fixed by the adhesive and which is fixed to one main surface of the base member, and a concave mirror holder to which the one side surface of the concave mirror is fixed by the adhesive and which is fixed to the one main surface of the base member.

6. The gas laser device according to claim 5,
wherein at least one of the convex mirror holder and the concave mirror holder is fixed to the one main surface by an adhesive.

7. The gas laser device according to claim 6,
wherein one of the convex mirror holder and the concave mirror holder is fixed to the one main surface by the adhesive, and the other thereof is mechanically fixed to the one main surface.

8. The gas laser device according to claim 1,
wherein a shape of the convex mirror when the reflection surface of the convex mirror is viewed from the front and a shape of the concave mirror when the reflection surface of the concave mirror is viewed from the front are rectangular.

9. The gas laser device according to claim 8,
wherein the one side surface of the convex mirror extends along a longitudinal direction of the convex mirror, and
the one side surface of the concave mirror extends along a longitudinal direction of the concave mirror.

10. The gas laser device according to claim 1,
wherein a width of the convex mirror in a direction perpendicular to the one side surface of the convex mirror and a width of the concave mirror in a direction perpendicular to the one side surface of the concave mirror are each 10 mm or more and 40 mm or less.

11. The gas laser device according to claim 1,
wherein a width of the convex mirror in a direction along an edge on a side of the reflection surface among edges of the one side surface of the convex mirror, and a width of the concave mirror in a direction along an edge on a side of the reflection surface among edges of the one side surface of the concave mirror are each 15 mm or more and 50 mm or less.

12. The gas laser device according to claim 1,
wherein the beam expander further includes a planar mirror including a reflection surface reflecting, toward the concave mirror, the light reflected by the convex mirror, and a plurality of side surfaces with only one side surface among the plurality of side surfaces fixed to the holding portion by an adhesive.

13. The gas laser device according to claim 12,
wherein the holding portion includes a convex mirror protrusion protruding from a surface to which the one side surface of the convex mirror is fixed by the adhesive and arranged around the convex mirror; a concave mirror protrusion protruding from a surface to which the one side surface of the concave mirror is fixed by the adhesive and arranged around the concave mirror; and a planar mirror protrusion protruding from a surface to which the one side surface of the planar mirror is fixed by the adhesive and arranged around the planar mirror.

14. The gas laser device according to claim 13,
wherein at least one set of the convex mirror protrusion and the convex mirror, the concave mirror protrusion and the concave mirror, and the planar mirror protrusion and the planar mirror is in a non-contact manner.

15. The gas laser device according to claim 13,
wherein at least one of the convex mirror, the concave mirror, and the planar mirror is surrounded by a corresponding protrusion among the convex mirror protrusion, the concave mirror protrusion, and the planar mirror protrusion.

16. The gas laser device according to claim 12,
wherein an optical axis of the light from the chamber device toward the convex mirror and an optical axis of the light from the concave mirror toward the output coupling mirror are located on the same straight line.

17. The gas laser device according to claim 1,
wherein the beam expander further includes a first planar mirror including a reflection surface reflecting the light reflected by the convex mirror, and a plurality of side surfaces with only one side surface among the plurality of side surfaces fixed to the holding portion by an adhesive; and a second planar mirror including a reflection surface reflecting the light, toward the concave mirror, reflected by the first planar mirror, and a plurality of side surfaces with only one side surface among the plurality of side surfaces fixed to the holding portion by an adhesive.

18. The gas laser device according to claim 17,
wherein the holding portion includes a convex mirror protrusion protruding from a surface to which the one side surface of the convex mirror is fixed by the adhesive and arranged around the convex mirror; a concave mirror protrusion protruding from a surface to which the one side surface of the concave mirror is fixed by the adhesive and arranged around the concave mirror; a first planar mirror protrusion protruding from a surface to which the one side surface of the first planar mirror is fixed by the adhesive and arranged around the first planar mirror; and a second planar mirror protrusion protruding from a surface to which the one side surface of the second planar mirror is fixed by the adhesive and arranged around the second planar mirror.

19. The gas laser device according to claim 1,
wherein the chamber device transmits laser light output from a laser oscillator and amplifies the laser light.

20. An electronic device manufacturing method, comprising:
generating pulse laser light using a gas laser device;
outputting the pulse laser light to an exposure apparatus; and
exposing a photosensitive substrate to the pulse laser light in the exposure apparatus to manufacture an electronic device,
the gas laser device including:
a chamber device including a pair of discharge electrodes facing each other and arranged at an internal space thereof in which a laser gas is filled, and configured to output light generated from the laser gas by a voltage being applied between the pair of discharge electrodes;
a resonator configured to cause the light output from the chamber device to resonate between both sides sandwiching the chamber device; and
a beam expander,
the resonator including an output coupling mirror arranged on one side of the sides sandwiching the chamber device, and being configured to cause a part of the light output from the chamber device to be transmitted therethrough, and another part of the light output from the chamber device to be reflected to return into the chamber device, and
the beam expander being arranged between the chamber device and the output coupling mirror, and including:
a holding portion;
a convex mirror including a reflection surface reflecting the light output from the chamber device to expand a beam width of the light, and a plurality of side surfaces with only one side surface among the plurality of side surfaces fixed to the holding portion by an adhesive; and
a concave mirror including a reflection surface reflecting the light reflected by the convex mirror toward the output coupling mirror so as to collimate the light so that the expanded beam width of the light becomes constant, and a plurality of side surfaces with only one side surface among the plurality of side surfaces fixed to the holding portion by an adhesive.
